(19) United States
(12) Patent Application Publication
(10) Pub. No.: US 2023/0031722 A1
(43) Pub. Date: Feb. 2, 2023

(54) Voltage Control for Etching Systems

(71) Applicant: Taiwan Semiconductor Manufacturing Co., Ltd., Hsinchu (TW)

(72) Inventors: Chansyun David YANG, Hsinchu (TW); Keh-Jeng CHANG, Hsinchu (TW); Chan-Lon YANG, Taipei City (TW); Perng-Fei YUH, Walnut Creek, CA (US)

(73) Assignee: Taiwan Semiconductor Manufacturing Co., Ltd., Hsinchu (TW)

(21) Appl. No.: 17/383,962

(22) Filed: Jul. 23, 2021

(51) Int. Cl. H01J 37/08; H01L 21/311; H01J 37/32

(52) U.S. Cl. CPC H01J 37/08; H01L 21/31116; H01J 37/32715; H01J 2237/0473; H01J 2237/334; H01J 2237/0475

(57) ABSTRACT

The present disclosure relates to an ion beam etching (IBE) system including a process chamber. The process chamber includes a plasma chamber configured to provide plasma. In addition, the process chamber includes an accelerator grid having multiple accelerator grid elements including a first accelerator grid element and a second accelerator grid element. A first wire is coupled to the first accelerator grid element and configured to supply a first voltage to the first accelerator grid element. A second wire is coupled to the second accelerator grid element and configured to supply a second voltage to the second accelerator grid element, where the second voltage is different from the first voltage. A first ion beam through a first hole is controlled by the first accelerator grid element, and a second ion beam through a second hole is controlled by the second accelerator grid element.

### BACKGROUND

With advances in semiconductor technology, there has been an increasing demand for higher storage capacity, faster processing systems, higher performance, and lower costs. To meet these demands, the semiconductor industry continues to scale down the dimensions of semiconductor devices. Such scaling down has increased the complexity of semiconductor manufacturing processes and the demands for the precision of features in semiconductor manufacturing systems.

### BRIEF DESCRIPTION OF THE DRAWINGS

Aspects of this disclosure are best understood from the following detailed description when read with the accompanying figures.

FIGS. 1A-1D illustrate cross-sectional views of an ion beam etching (IBE) system with various voltage supplies for an accelerator grid, in accordance with some embodiments.

FIG. 1E illustrates example voltages supplied for an accelerator grid, in accordance with some embodiments.

FIG. 1F illustrates a cross-sectional view of an IBE system with various voltage supplies for an accelerator grid, in accordance with some embodiments.

FIGS. 2A-2C illustrate isometric view and cross-sectional views of a semiconductor device with contact structures formed using an IBE system, in accordance with some embodiments.

FIGS. 2D-2G illustrate cross-sectional views of a semiconductor device with contact structures at various stages of its fabrication process using an IBE system, in accordance with some embodiments.

FIGS. 2H-2J illustrate top views of a semiconductor device with contact structures formed using an IBE system, in accordance with some embodiments.

FIG. 3 is a flow chart of a method for performing directional etching with an IBE system having various voltage supplies for an accelerator grid, in accordance with some embodiments.

FIGS. 4A-4B illustrate cross-sectional views of more details of directional etching performed on features of a semiconductor device using an IBE system having various voltage supplies for an accelerator grid, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

Ion beam etching (IBE) is a process that utilizes an inert gas plasma to bombard an etching target (e.g., a wafer) with ions to remove materials from the wafer. An IBE system includes a plasma chamber and a multi-grid (e.g., three-grid) optics system. In description below, a three-grid system is used as an example of a multi-grid optics system. The three-grid system has numerous electrostatic apertures (holes) separated from each other, e.g., sometimes by a few millimeters. Applying specific voltages to each grid, the three-grid system controls the holes and ion beams through the holes. In detail, the three-grid system extracts positively charged ions from inductively coupled plasma (ICP, also referred to as inductively coupled discharge plasma) generated in the plasma chamber. In addition, the three-grid system further accelerates and directs the ions through the holes to form mono-energetic beams of the ions, or ion beams, to etch materials by physical sputtering on the wafer. Controlled by the three-grid system, an individual ion beam is created through each hole. The combination of the ion beams controlled by the three-grid system form a single broad beam to bombard the etching target. In an IBE process, an etching target (e.g., a wafer) can be placed with a tilted angle and/or a rotated angle to allow an angle of incidence of the ions onto the surface of the wafer. Such control of the ion incidence on the wafer affects sputtering yield and the resulting topography, hence substantially improving etching profiles of the etching target.

Accordingly, an IBE process can provide directional flexibility that is not available in other plasma processes. An IBE system can perform a directional etching process to create a feature (e.g., an opening) on a photoresist layer or a physical layer of a wafer, where the opening can have different lengths in different dimensions. For example, an IBE system can expand a square opening with a critical dimension (CD) to be larger in one dimension along an X-axis without changing a dimension along a Y-axis. As a result, the IBE process can compensate the extreme ultraviolet (EUV) lithography resolution limitation at small critical dimension patterning. While the etching rate with the IBE process is typically lower than the etching rate for a reactive ion etching (RIE) process, the IBE process can offer a high precision for applications that demand high dimension profile control. Also, the IBE process can be used to remove materials where an RIE process may not be successful. The IBE process can etch alloys and composite materials that are not compatible with an RIE process.

One of the challenges of the IBE process can be preventing asymmetry etching. When a wafer is placed within a process chamber of an IBE system with a tilted angle and/or rotated angle, different ion beams through the holes of the three-grid system have different incidence distances to the wafer. An incidence distance of an ion beam to the wafer is a distance from the source of the ion, or simply referred to as an ion source, to a location of the wafer, where the location is an incidence point of the ion beam on the surface of the wafer. Therefore, ions in different ion beams travel different incidence distances to reach the different locations of the wafer surface, resulting in different etching rates at different locations of the wafer surface. The etching rate at a first location of the tilted wafer by a first ion beam is lower when an incidence distance of the first ion beam is longer, while the etching rate at a second location of the tilted wafer by a second ion beam is higher when an incidence distance of the second ion beam is shorter. As a result, the etching amount at the first location is smaller than the etching amount at the second location, resulting in an asymmetry etching behavior for the IBE process. In general, the etching rate at a location of a tilted wafer surface is inversely proportional to an incidence distance of the corresponding ion beam incidence to the location. Rotation of the tilted wafer does not overcome the challenges of preventing asymmetry etching.

In an IBE system, the three-grid system includes a screen grid, an accelerator grid, and a decelerator grid to control the ion beams to strike the wafer. The screen grid, the accelerator grid, or the decelerator grid, includes multiple elements, such as multiple screen grid elements, multiple accelerator grid elements, and multiple decelerator grid elements. A screen grid element, an accelerator grid element, and a decelerator grid element together control a hole and an ion beam through the hole. All the screen grid elements are supplied by a same screen voltage, all the accelerator grid elements are supplied by a same accelerator voltage, and all the decelerator grid elements are supplied by a same decelerator voltage. Therefore, all the ion beams of the IBE systems are controlled by electric fields of the same energy. Under the same energy, when ions in two different ion beams go through two different incidence distances to reach two locations of the wafer surface, two different etching rates are resulted at the two locations.

The present disclosure provides example IBE systems that can generate substantially uniformly etching across different locations of a surface of a tilted wafer within the process chamber of the IBE systems. In some embodiments, the voltages supplied to the accelerator grid elements can be varied to control different ion beams. Instead of having a same voltage supplied to different accelerator grid elements, some embodiments have different voltages supplied to different accelerator grid elements. As a result, an accelerator grid element controlling an ion beam having a longer incidence distance can be supplied a voltage to create an electric field with a higher energy to transport the ions in the ion beam. Thus, the higher the energy in the electric field generated by the voltage, the longer the incidence distance the accelerator grid element can compensate, resulting in uniformly etching across a surface of a tilted wafer. Accordingly, the multiple voltages for multiple accelerator grid elements can balance all locations in the rotated tilted wafer with equal directional etching. As a result, embodiments herein reduce IBE asymmetry etching behavior. A tilted wafer has uniformly etching across different locations of a surface of the tilted wafer when an etching amount at a first location is substantially same as an etching amount at a second location, where the first location and the second location can be any location of the surface of the tilted wafer.

In some embodiments, holes of a three-grid system in the IBE system can be divided into multiple zones separated by an insulator. A first zone includes a first group of one or more holes controlled by a first group of one or more accelerator grid elements coupled to a first wire to receive a first voltage. Similarly, a second zone includes a second group of one or more holes controlled by a second group of one or more accelerator grid elements coupled to a second wire to receive a second voltage. The second voltage is different from the first voltage. As a result, the first group of one or more accelerator grid elements has an energy different from the second group of one or more accelerator grid elements to transport ions in ion beams through the first group of one or more holes. The voltage difference between the first voltage and the second voltage is determined so that the energy difference for controlling the ion beams compensates the difference of the incidence distances of the ion beams. Hence, the IBE asymmetry etching behavior can be reduced.

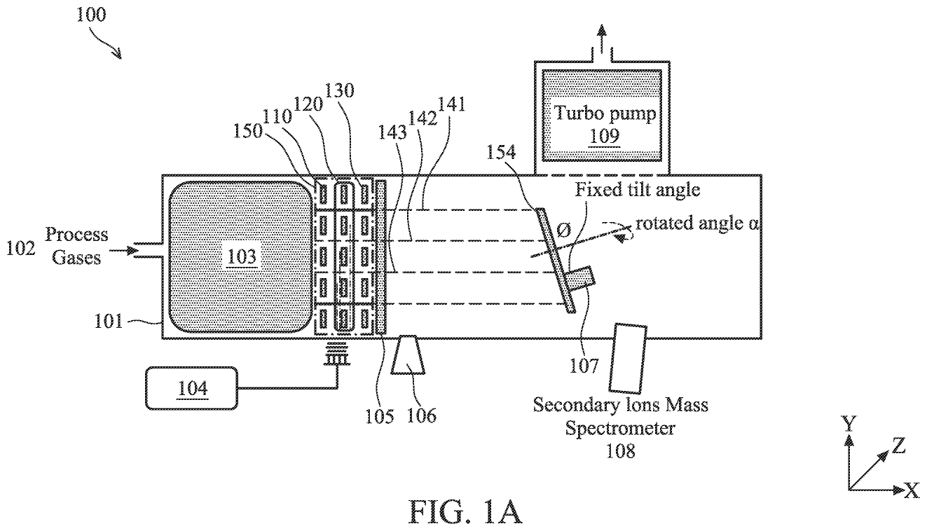

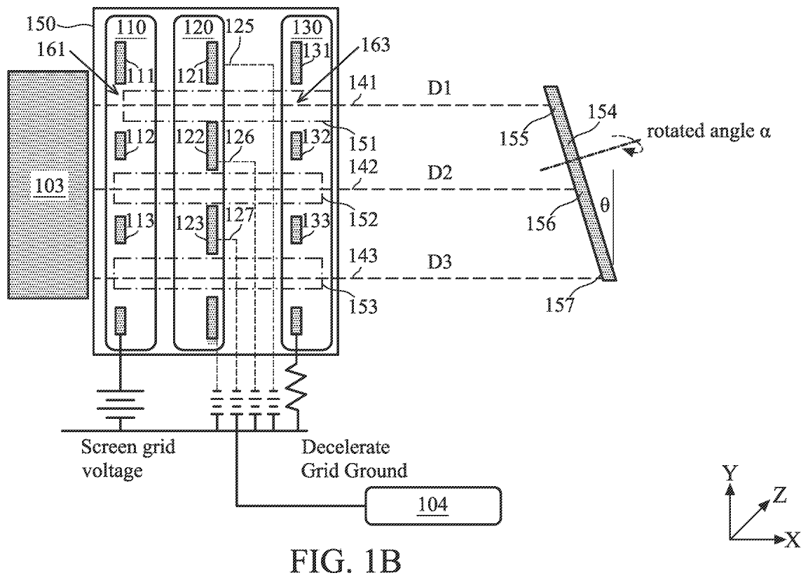

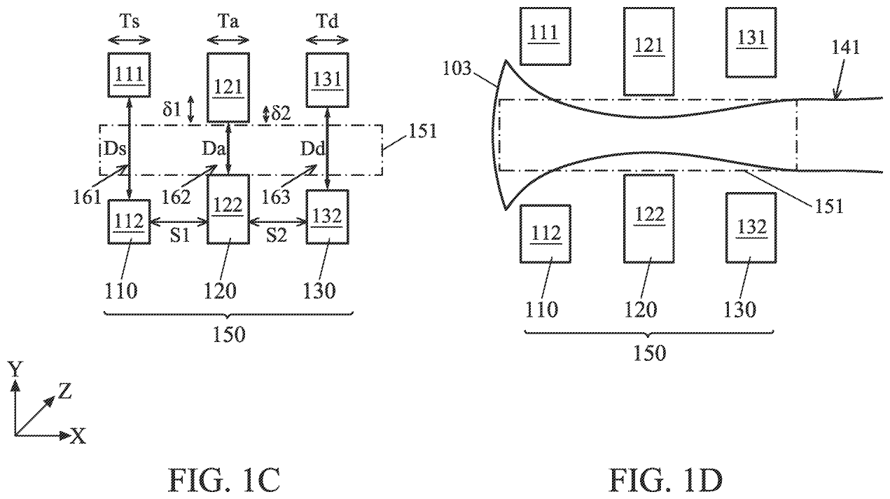

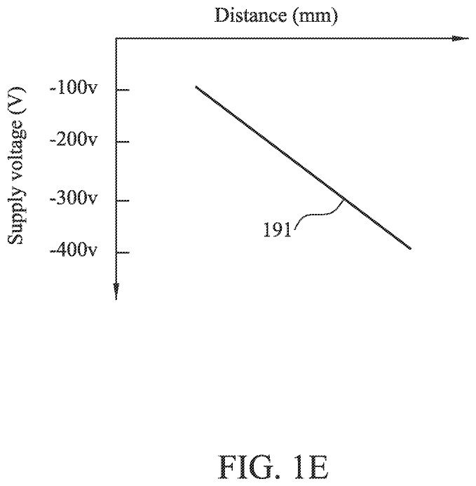

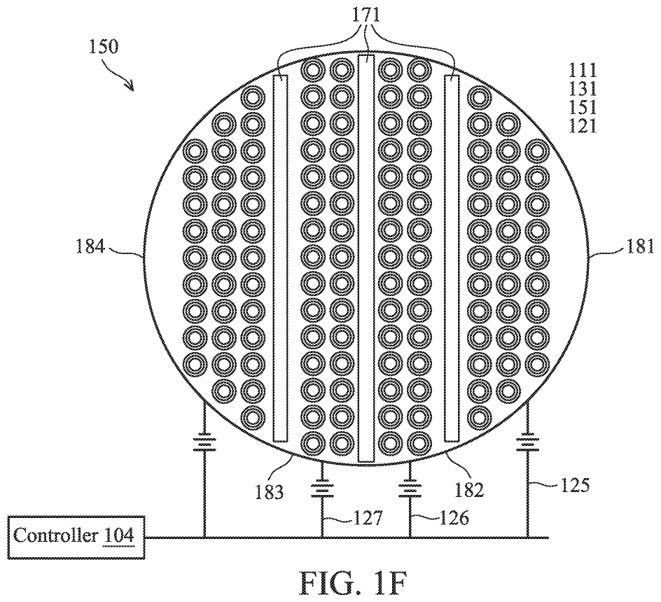

FIGS. 1A-ID illustrate cross-sectional views of an ion beam etching (IBE) system with various voltage supplies for an accelerator grid, in accordance with some embodiments. FIG. 1E illustrates example voltages supplied for an accelerator grid, in accordance with some embodiments. FIG. 1F illustrates a cross-sectional view of an IBE system with various voltage supplies for an accelerator grid, in accordance with some embodiments.

In some embodiments, as shown in FIG. 1A, IBE system 100 can include a process chamber 101 having an inlet 102 to receive an inert gas, such as a noble gas. Process chamber 101 can include a plasma chamber 103 configured to provide plasma, and a three-grid system 150 including a screen grid 110, an accelerator grid 120, and a decelerator grid 130. Multiple holes are formed in three-grid system 150, with more details shown in FIG. 1B. Ions generated from the plasma within plasma chamber 103 go through the multiple holes to form multiple ion beams, such as an ion beam 141, an ion beam 142, and an ion beam 143. In addition, process chamber 101 can include a control unit 104, a mechanical shutter 105, a plasma bridge neutralizer 106, a rotating fixture 107 configured to hold a wafer 154, a secondary ions mass spectrometer 108, and a pump 109 to pre-pump and exhaust process chamber 101. Wafer 154 can have a tilted angle θ with respect to a first direction (e.g., along a Y-axis) and a rotated angle α with respect to a second direction (e.g., along a Z-axis). In some embodiments, ion beam 141, ion beam 142, and ion beam 143 can reach wafer 154 along a third direction (e.g., along an X-axis).

IBE system 100 can use an inert gas (e.g., argon or a noble gas) received from inlet 102 to generate ICP in plasma chamber 103. In addition, being electrically biased, three-grid system 150 can extract positively charged ions from the ICP and provide ions as ion beams through the multiple holes of three-grid system 150 to bombard wafer 154 to remove material from wafer 154. For example, argon ions can be extracted from an ICP source, accelerated and directed by three-grid system 150 to form mono-energetic beams, such as ion beam 141, ion beam 142, and ion beam 143 to etch any materials, such as piezoelectric and ferroelectrics, magnetics materials, group III-V elements of the periodic table (e.g., GaAs, InP, GaN, AlN . . . ), ohmic metals (e.g., Au, Pt, Cu, Ir . . . ), and hard mask materials (e.g., Ag, TiWN, Ni . . . ) on wafer 154. In some embodiments, IBE system 100 can have a wide range energy capability (from about 50 V to about 800 V) for low ion damage or for fast etch of various materials.

In some embodiments, plasma chamber 103, which can be an ICP source, can include a 350 mm diameter quartz vessel with a radio frequency (RF) plasma generator. An antenna (not shown) can be wrapped around the quartz vessel for inductive coupling. The antenna can operate at about 1.8 MHz and about 2 kW power. The oscillating current in the antenna at about 1.8 MHz can induce an electromagnetic field in the quartz vessel. During plasma ignition, some primary electrons can collect the electromagnetic field energy and agitate accordingly. Main plasma can be created inside the quartz vessel of plasma chamber 103 by inelastic collisions between hot electrons and neutrals (injected Argon gas) which generate ions/electrons pairs.

Three-grid system 150 can extract ions from plasma within plasma chamber 103, and accelerate the ions to build mono-energetic beams, e.g., ion beam 141, ion beam 142, ion beam 143 through multiple holes of three-grid system 150. This can be done by applying specific voltages to each grid of three-grid system 150, which will be shown in more details in FIG. 1B. The inner grid, which is screen grid 110, can be in contact with plasma source 103, and can be biased positive relative to a ground voltage. There are some space shown in FIG. 1A between screen grid 110 and plasma source 103 for illustration purposes. The second grid, which is accelerator grid 120, can be biased negative relative to the ground voltage and therefore even more negative relative to the screen grid. This total potential difference between the screen grid and the accelerator grid can create an electric field. Positive ions in the plasma within plasma source 103 that drift close to this electric field can be extracted through the grids' holes and can be accelerated, while electrons can be separated and kept inside plasma source 103. The third grid, which is decelerator grid 130, can be held at ground voltage. Decelerator grid 130 reduces divergence of the ion beams and can create another electric field which can prevent electrons emitted by plasma bridge neutralizer 106 from back-streaming into three-grid system 150.

Mechanical shutter 105 can be placed downstream of three-grid system 150. When closed, process chamber 101 is protected and no etching takes place. This closed position allows for stabilization of the different parts such as plasma source, beam voltage, ions acceleration, and more. Mechanical shutter 105 is open when the whole system is stable (e.g. ions beam fully collimated and mon-energetic, substrate fixture correctly clamped and cooled-down, etc.) to ensure constant, precise, and repeatable processes.

Plasma bridge neutralizer (PBN) 106 is an electrons source placed downstream from three-grid system 150 to neutralize the charged ion beam. The electrons cannot back-stream into three-grid system 150 because of the negative decelerator-accelerator electric field. These electrons do not combine with the ions present in the beam, but they provide a charge balance for the ions in order to avoid space or surface charging on wafer 154.

Secondary ions mass spectrometer 108 can be used to monitor sputtered material species, allowing etching to be stopped at specific layers. When wafer 154 is bombarded by the ion beams, e.g., ion beam 141, ion beam 142, and/or ion beam 143, secondary ions can be ejected from the surface of wafer 154. These ejected secondary ions can be collected and a mass analyzer (quadrupole) can isolate them according to their mass in order to determine the elemental composition of the sputtered surface. A detection system (electron multiplier) can amplify and display the counts (magnitude) of the secondary ions in real time.

In addition, IBE system 100 can include other structural and functional components, such as RF generators, matching circuits, chamber liners, control circuits, actuators, power supplies, exhaust systems, etc. which are not shown for simplicity.

FIG. 1B illustrates further details of three-grid system 150 including screen grid 110, accelerator grid 120, and decelerator grid 130. Screen grid 110 can include multiple screen grid elements, such as a screen grid element 111, a screen grid element 112, a screen grid element 113, and more. The multiple screen grid elements, e.g., screen grid element 111, screen grid element 112, and screen grid element 113, are in contact with plasma chamber 103. Accelerator grid 120 is disposed adjacent to and separated from screen grid 110. Accelerator grid 120 includes multiple accelerator grid elements, e.g., an accelerator grid element 121, an accelerator grid element 122, an accelerator grid element 123, and more. Decelerator grid 130 is disposed adjacent to and separated from accelerator grid 120. Decelerator grid 130 includes multiple decelerator grid elements, e.g., a decelerator grid element 131, a decelerator grid element 132, a decelerator grid element 133, and more. Three-grid system 150 includes multiple holes, e.g., a hole 151, a hole 152, a hole 153, and more. In some embodiments, the holes, e.g., hole 151, hole 152, or hole 153, include molybdenum electrostatic apertures of various diameters at different grid elements. For example, hole 151 includes an aperture 161 at screen grid 110, an aperture 162 at accelerator grid 120, and an aperture 163 at decelerator grid 130. Apertures 161, 162, and 163 have different diameters. More details of hole 151 are shown in FIG. 1C.

As shown in FIG. 1C, a diameter Ds of apertures 161 on screen grid 110 can be greater than a diameter Da of aperture 162 on accelerator grid 120. And a diameter Dd of aperture 163 on decelerator grid 130 can be greater than diameter Da of aperture 162 on accelerator grid 120. As a result, apertures 162 can be seen inside apertures 161 in FIG. 1F. In some embodiments, diameter Ds can range from about 4 mm to about 7 mm. Diameter Da can range from about 2 mm to about 5 mm. Diameter Dd can range from about 3 mm to about 7 mm. For example, diameter Ds can be about 5 mm, diameter Da can be about 3.5 mm, and diameter Dd can be about 5.5 mm. In some embodiments, a difference δ1 between diameters Ds and Da can range from about 0.5 mm to about 4 mm. In some embodiments, a different Ω between diameters Dd and Da can range from about 0.5 mm to about 2.5 mm. For example, difference δ1 can be about 1.5 mm and difference δ2 can be about 1 mm. Screen grid 110 with diameter Ds greater than diameter Da of accelerator grid 120 can increase the number of ions in ion beam 136 through hole 151. Accelerator grid 120 with diameter Da less than diameter Ds can accelerate and focus ions in ion beam 141. In some embodiments, diameter Ds can be greater than, less than, or the same as diameter Dd. In some embodiments, screen grid 110 can have a thickness Ts along an X-axis ranging from about 0.3 mm to about 0.8 mm. In some embodiments, accelerator grid 120 can have a thickness Ta along an X-axis ranging from about 0.4 mm to about 1 mm. In some embodiments, decelerator grid 130 can have a thickness Td along an X-axis ranging from about 0.4 mm to about 1.2 mm. For example, thickness Ts can be about 0.4 mm, thickness Ta can be about 0.5 mm, and thickness Td can be about 0.7 mm. In some embodiments, a separation space S1 between screen grid 110 and accelerator grid 120 along an X-axis can range from about 0.4 mm to about 0.6 mm. And a separation space S2 between accelerator grid 120 and decelerator grid 130 along an X-axis can range from about 0.5 mm to about 0.7 mm. For example, separation space S1 can be about 0.5 mm and separation space S2 can be about 0.6 mm. With the configurations of screen grid 110, accelerator grid 120, and decelerator grid 130 as shown in FIGS. 1C-1D, ions in plasma chamber 103 can be focused through these grids without direct interception and form ion beam 141 through hole 151.

Referring back to FIG. 1B, screen grid 110 is supplied by a screen grid voltage to extract ions from the plasma within plasma chamber 103. On the other hand, different accelerator grid elements can be supplied by different voltages through different wires. A wire 125 is coupled to accelerator grid element 121 and configured to supply a first voltage to accelerator grid element 121. A wire 126 is coupled to accelerator grid element 122 and configured to supply a second voltage to accelerator grid element 122. A wire 127 is coupled to accelerator grid element 123 and configured to supply a third voltage to accelerator grid element 123. The first voltage, the second voltage, and the third voltage can be different from each other.

Ions generated from the plasma within plasma chamber 103 go through the multiple holes to form multiple ion beams, e.g., ion beam 141 through hole 151, ion beam 142 through hole 152, ion beam 143 through hole 153, and more. The multiple ion beams perform directional etching on wafer 154. An ion beam through a hole is controlled by a combination of a screen grid element, an accelerator grid element, and a decelerator grid element. For example, ion beam 141 is controlled by screen grid element 111, accelerator grid element 121, and decelerator grid element 131. Similarly, ion beam 142 is controlled by screen grid element 112, accelerator grid element 122, and decelerator grid element 132. Ion beam 143 is controlled by screen grid element 113, accelerator grid element 123, and decelerator grid element 133.

Ion beam 141 reaches the surface of wafer 154 at an incidence point 155. Hence, ion beam 141 has an incidence distance D1 measured from the source of ion beam 141, or an ion source, to point 155. The source of ion beam 141 can be counted as the external edge of plasma chamber 103 where the ions are extracted from. Similarly, ion beam 142 has an incidence distance D2 measured from the source of ion beam 142 to an incidence point 156 of ion beam 142. Ion beam 143 has an incidence distance D3 measured from the source of ion beam 143 to an incidence point 157 of ion beam 143. The source of ion beam 141, the source of ion beam 142, and the source of ion beam 143, can be a same or parallel aligned. In some embodiments, the incidence distance D1, the incidence distance D2, and incidence distance D3, are different from each other.

Therefore, ions in different ion beams travel different incidence distances to reach the different locations of the wafer surface. The differences in the incidence distances of ion beams can result in different etching rates at different locations of the wafer surface. An etching rate at a point of wafer 154 can be a function of the energy of the ions reaching the point and the distance of the ions travel to reach the point, e.g., the incidence distance of the ion beam. In general, the etching rate at a location of a tilted wafer surface is near inversely proportional to an incidence distance of the corresponding ion beam incidence to the location. When all ion beams are supplied by the same energy, the etching rate of point 157 by ion beam 143 can be lower than the etching rate of point 156 by ion beam 142, since the incidence distance of ion beam 143 is longer than the incidence distance of ion beam 142. Rotation of the tilted wafer would not be able to solve the asymmetry etching behavior problem for the IBE process.

In some embodiments, accelerator grid element 121, accelerator grid element 122, and accelerator grid element 123 are supplied by different voltages to generate electric fields of different energies. Thus, compared to accelerator grid element 122, accelerator grid element 123 is supplied by the third voltage to generate an electric field of higher energy since ion beam 143 from hole 153 controlled by accelerator grid element 123 has longer incidence distance than ion beam 142 from hole 152 controlled by accelerator grid element 122. As a result, the etching rate at point 157 by ion beam 143 can be the same as the etching rate at point 156 by ion beam 142. Similarly, the etching rate at point 156 by ion beam 142 can be the same as the etching rate at point 155 by ion beam 141 when accelerator grid element 122 is supplied by the second voltage to generate an electric field of higher energy. Ion beam 142 from hole 152 controlled by accelerator grid element 122 has longer incidence distance than ion beam 141 from hole 151. As a result, by adjusting the different voltages supplied to the different accelerator grid elements to vary the energy of the electric field for the ion beams, an improved or close to uniformed distributed etching rate can be achieved for different points, e.g., point 155, point 156, and point 157.

In some embodiments, point 155, point 156, and point 157 can be located near the top edge, the middle, and the bottom edge of wafer 154 with about equal distance between them. Therefore, the first voltage supplied to accelerator grid element 121, the second voltage supplied to accelerator grid element 122, and the third voltage supplied to accelerator grid element 123, can have equal difference between them. For example, the first voltage can be about −200 volt, the second voltage can be about −240 volt, and the third voltage can be about −280 volt. In some embodiments, a difference between the first voltage and the second voltage is about 100 volt when the tilted angle θ of wafer 154 is between about 300 and about 600 degrees, the difference between the first voltage and the second voltage is about 400 volt when the tilted angle θ is between about 5° and about 300 degrees.

In some embodiments, FIG. 1E illustrates an example voltages supplied for an accelerator grid shown by a curve 191, in accordance with some embodiments. The voltages supplied to the various accelerator grid elements can depend on different incidence distances the ions in different ion beams travel to reach the different locations of the wafer surface. For example, when the incidence distance of the ion beam is 100 mm, the supplied voltage can be about −100 V. On the other hand, when the incidence distance of the ion beam is 3000 mm, the supplied voltage can be about −400 V. The relationship shown by curve 191 is only for examples and not limiting. There can be other formats to assign the voltages to be supplied to the various accelerator grid elements. The detailed voltage assignments can be determined based on experience and data set collected from etching wafer 154.

Referring back to FIG. 1B, in some embodiments, control unit 104 is configured to control various operations of IBE system 100, e.g., supplying voltages for three-grid control system 150. The screen grid voltage supplied to screen gird 110 can be a positive voltage with respect to a ground voltage, while the first voltage, the second voltage, and the third voltage are negative voltages with respect to the ground voltage. In some embodiments, the screen grid voltage is about 1200 volt, the first voltage is about −200 volt, the second voltage is about −240 volt, and the third voltage is about −280 volt.

FIG. 1F illustrates further details of three-grid system 150 including screen grid 110, accelerator grid 120, and decelerator grid 130. Three-grid system 150 can be divided into four zones, a zone 181, a zone 182, a zone 183, and a zone 184. The four zones are shown merely as an example. In some other embodiments, there can be different number of zones for the three-grid system 150. Hole 151 is within zone 181, hole 152 is within zone 182, and hole 153 is within zone 183. In addition, zone 181 further includes multiple other holes controlled by a first group of one or more accelerator grid elements coupled to first wire 125 to supply the first voltage as supplied to hole 151. Similarly, zone 182 further includes multiple other holes controlled by a second group of one or more accelerator grid elements coupled to second wire 126 to supply the second voltage as supplied to hole 152. Zone 183 further includes multiple other holes controlled by a third group of one or more accelerator grid elements coupled to third wire 127 to supply the third voltage as supplied to hole 153.

Table 1 below shows example voltages supplied to the screen grid, the decelerator grid, and the various accelerator grid elements in different zones. In addition, the supplied voltage can be impacted by the tilted angle θ of wafer 154. For example, when the tilted angle is 01, the accelerated voltage assigned to the accelerated elements in different zones can be about −200 V, about −240 V, about −280 V, and about −320 V. On the other hand, when the tilted angle is 02<01, the accelerated voltage assigned to the accelerated elements in different zones can be about −200 V, about −220 V, about −240 V, and about −260 V. The detailed voltage assignments can be determined based on experience and data set collected from etching wafer 154.

TABLE 1

| | | Voltage | | | |
|---|---|---|---|---|---|
| | Tunable accelerate bias | Zone 1 | Zone 2 | Zone 3 | Zone 4 |
| | Case 1 titled | | | | |
| | angle θ1 | | | | |
| 1^{st} grid | Screen grid hole | 1200 v | 1200 v | 1200 v | 1200 v |
| 2^{nd} grid | Accelerator grid hole | −200 v | −240 v | −280 v | −320 v |
| 3^{rd} grid | decelerator grid hole | 0 | 0 | 0 | 0 |
| | Case 2 titled | | | | |
| | angle θ2 < θ1 | | | | |
| 1^{st} grid | Screen grid hole | 1200 v | 1200 v | 1200 v | 1200 v |
| 2^{nd} grid | Accelerator grid hole | −200 v | −220 v | −240 v | −260 v |
| 3^{rd} grid | decelerator grid hole | 0 | 0 | 0 | 0 |

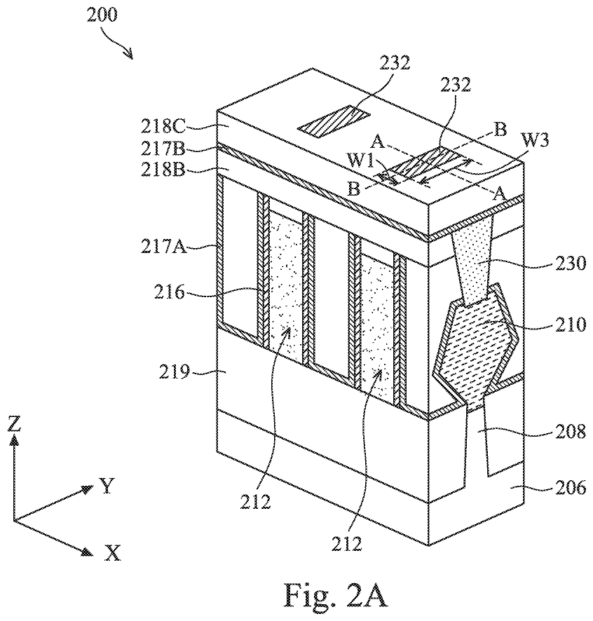

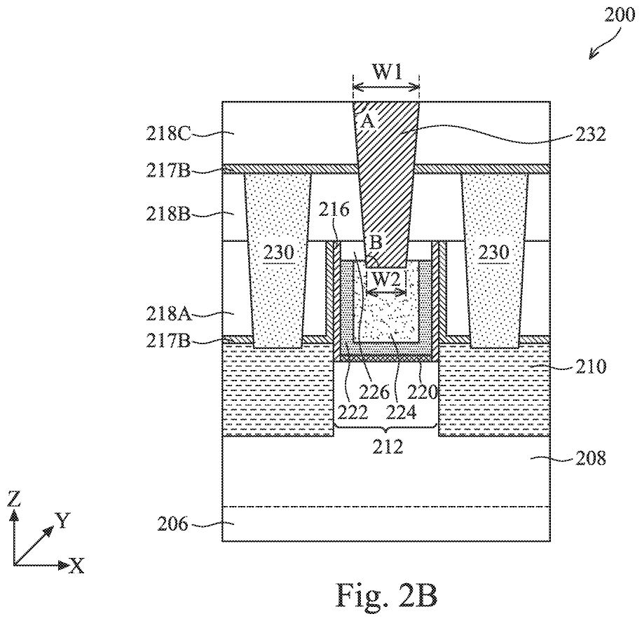

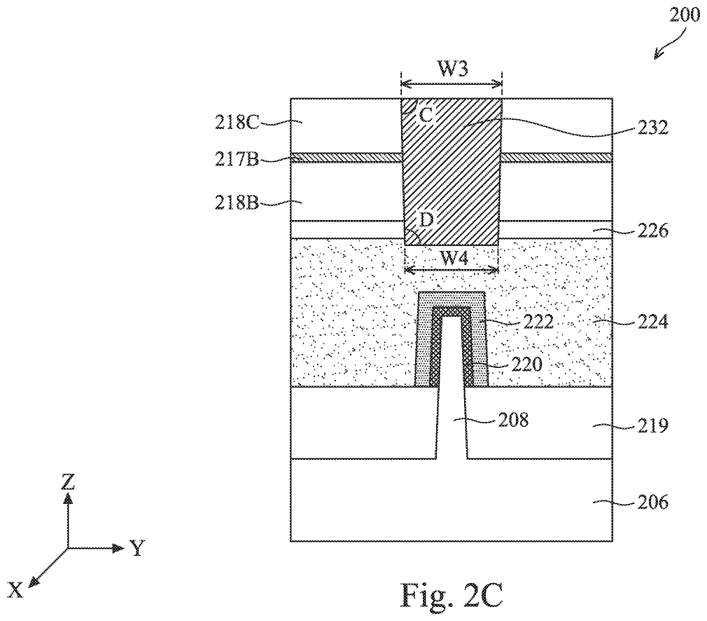

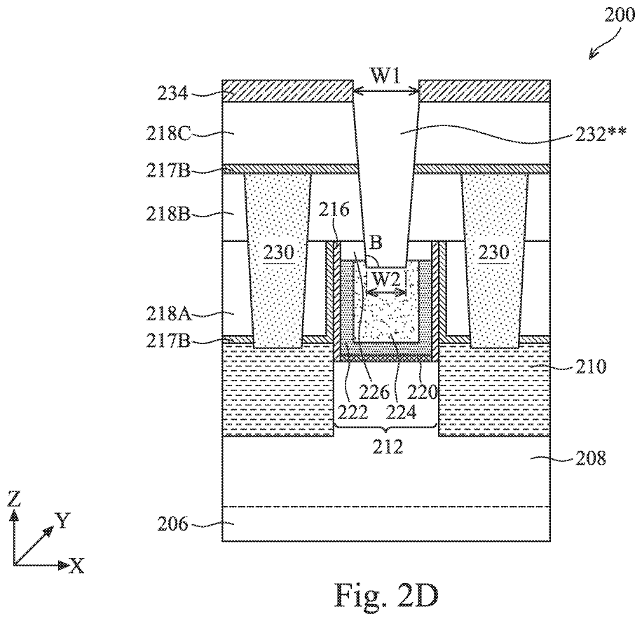

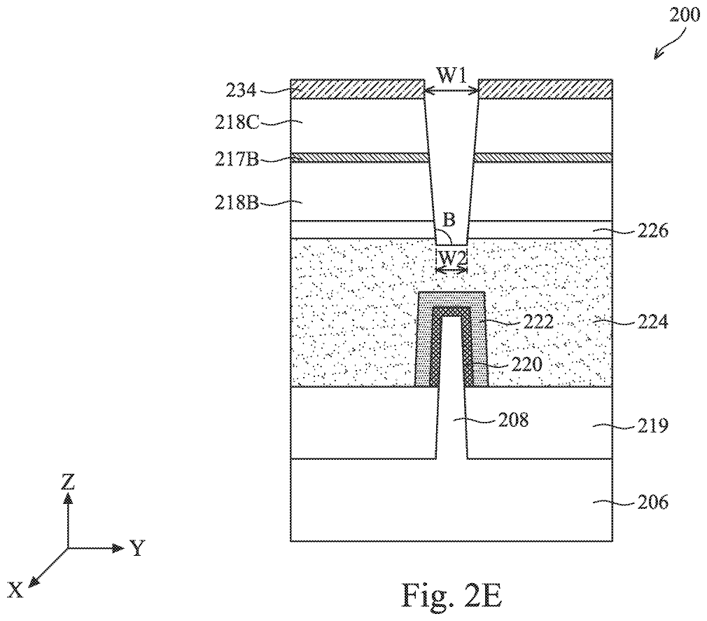

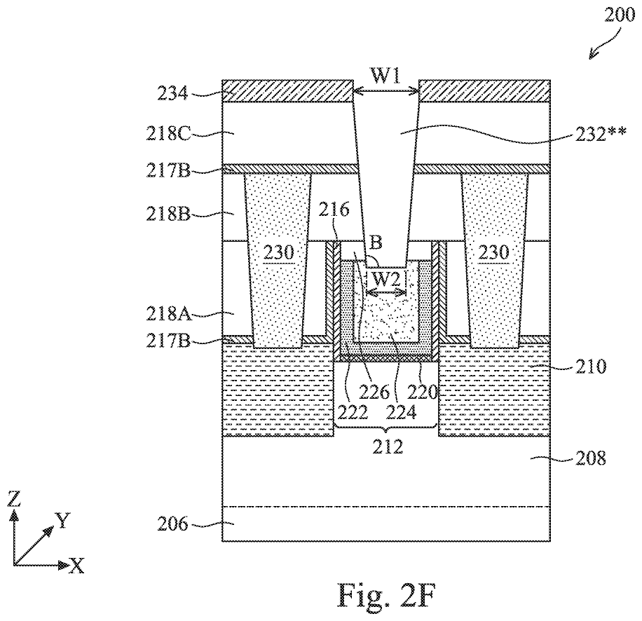

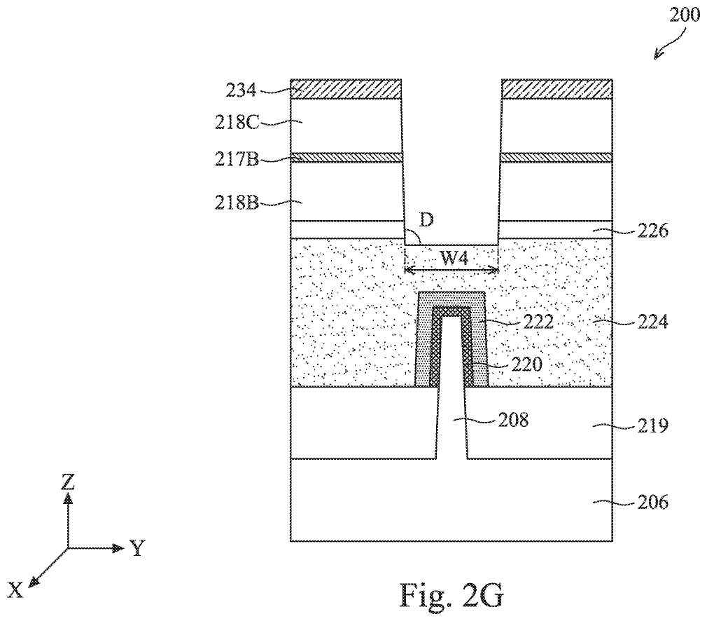

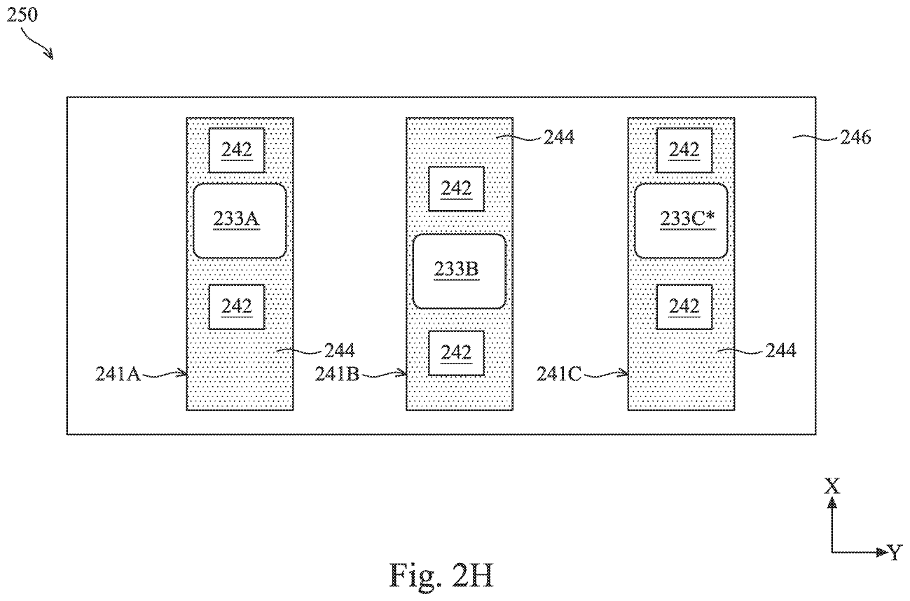

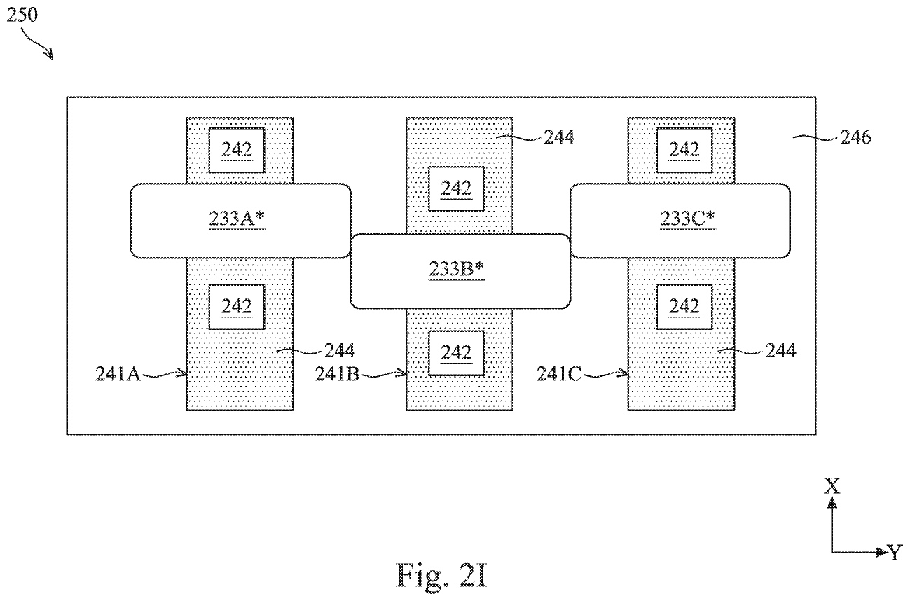

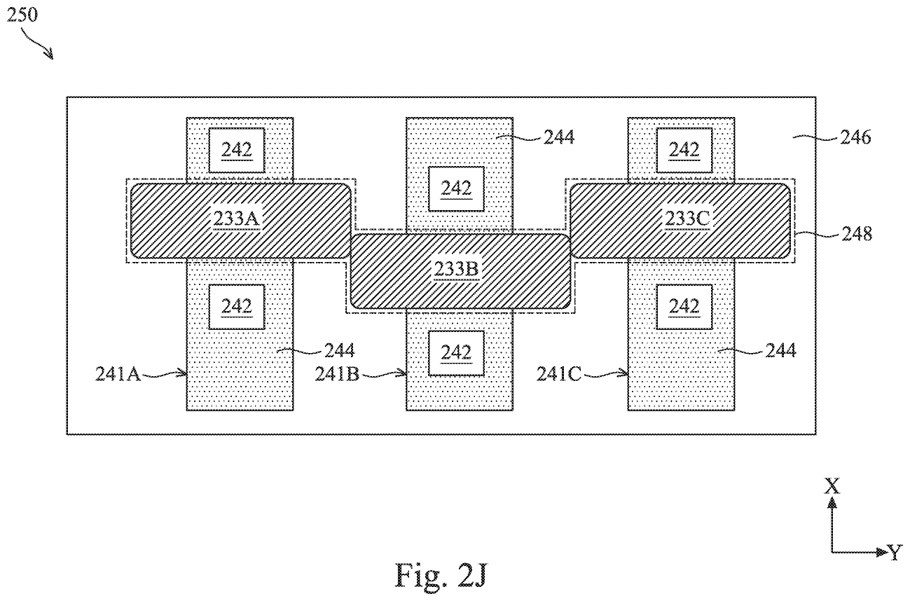

FIG. 2A illustrate an isometric view of a field effect transistor (FET) 200 (also referred to as semiconductor device 200) after the formation of gate contact structures 232 using IBE system 100, according to some embodiments. FIGS. 2B, 2D, and 2F illustrate cross-sectional views of FET 200 along line A-A of FIG. 2A and FIGS. 2C, 2E, and 2G illustrate cross-sectional views along line B-B of FIG. 2A with additional structures that are not shown in FIG. 2A for simplicity. The discussion of elements in FIGS. 2A-2G with the same annotations applies to each other, unless mentioned otherwise. In some embodiments, FET 200 can represent n-type FET 200 (NFET 200) or p-type FET 200 (PFET 200) and the discussion of FET 200 applies to both NFET 200 and PFET 200, unless mentioned otherwise.

Referring to FIG. 2A, FET 200 can include an array of gate structures 212 disposed on a fin structure 208, gate contact structures 232 disposed on gate structures 212, an array of S/D regions 210 (one of S/D regions 210 visible in FIG. 2A) disposed on portions of fin structure 208 that are not covered by gate structures 212, and S/D contact structures 230 (one of S/D contact structures 230 visible in FIG. 2A). FET 200 can further include gate spacers 216, shallow trench isolation (STI) regions 219, etch stop layers (ESLs) 217A-217B, and interlayer dielectric (ILD) layers 218A-218C. In some embodiments, gate spacers 216, STI regions 219, ESLs 217A-217B, and ILD layers 218A-218C can include an insulating material, such as silicon oxide, silicon nitride (SiN), silicon carbon nitride (SiCN), silicon oxycarbon nitride (SiOCN), and silicon germanium oxide.

FET 200 can be formed on a substrate 206. There may be other FETs and/or structures (e.g., isolation structures) formed on substrate 206. Substrate 206 can be a semiconductor material, such as silicon, germanium (Ge), silicon germanium (SiGe), a silicon-on-insulator (SOI) structure, and a combination thereof. In some embodiments, fin structure 208 can include a material similar to substrate 206 and extend along an X-axis.

Referring to FIGS. 2A-2B, S/D regions 210 can include epitaxially-grown semiconductor material, such as Si or SiGe, and n-type dopants, such as phosphorus or p-type dopants, such as boron. S/D contact structures 230 are disposed on S/D region 210 and within ILD layers 218A-218B and ESL 217A. In some embodiments, S/D contact structure 230 can include a silicide layer and a contact plug disposed on the silicide layer. In some embodiments, via structures (not shown) can be disposed on S/D contact structures 230 and within ILD layer 218C and ESL 217B.

Referring to FIGS. 2A-2C, each of gate structures 212 can include an interfacial oxide (IO) layer 220, a high-k (HK) gate dielectric layer 222, a gate metal fill layer 224, and a gate capping layer 226. Gate contact structure 232 can be disposed on gate structure 212 through ILD layers 218B-218A, ESL 217B, and gate capping layer 226. In some embodiments, gate contact structure 232 can have dimensions W3-W4 along a Y-axis greater than dimension W1-W2 along an X-axis. In some embodiments, the ratio of W1:W3 can range from about 1:2 to about 1:4 and the ratio of W2:W4 can range from about 1:2 to about 1:4. Dimensions W1 and W3 are dimensions of the top surface of gate contact structure 232 and dimensions W2 and W4 are dimensions of the base of gate contact structure 232. In some embodiments, dimension W1 can range from about 27 nm to about 33 nm, dimension W2, which is smaller than dimension W2, can range from about 20 nm to about 24 nm, dimension W3 can range from about 50 nm to about 55 nm, and dimension W4, which is equal to or smaller than dimension W4, can range from about 50 nm to about 55 nm.

In some embodiments, such dimensions of gate contact structure 232 can be formed using IBE system 100. The use of IBE system 100 to form gate contact structure 232 with different dimensions along X- and Y-axis can simplify the fabrication of gate contact structure 232 and improve its fabrication process control, as described below. In some embodiments, sidewalls of gate contact structure 232 formed using IBE system 100 can have different angles with the top surface and base of gate contact structure 232 along different planes. For example, the sidewalls of gate contact structure 232 extending along a ZY-plane can form angle A with the top surface and angle B with the base of gate contact structure 232, as shown in FIG. 2B. On the other hand, the sidewalls of gate contact structure 232 extending along a ZX-plane can form angle C with the top surface and angle D with the base of gate contact structure 232, as shown in FIG. 2C. Angle A can be smaller than angle C and angle B can be greater than angle D. As a result, the sidewalls of gate contact structure 232 along a ZX-plane can be more vertical than the sidewalls of gate contact structure 232 along a ZY-plane. That is, the sidewalls of gate contact structure 232 along a ZX-plane can have a greater slope than the sidewalls of gate contact structure 232 along a ZY-plane.

FIGS. 2D-2G illustrate cross-sectional views of FET 200 at various stages of fabricating gate contact structure 232 using IBE system 100, according to some embodiments. The formation of gate contact structure 232 can include sequential operations of forming gate contact openings 232* (shown in FIGS. 2D-2E) and 232** (shown in FIGS. 2F-2G), filling gate contact opening 232** with conductive material, and performing a chemical mechanical polish (CMP) to form the structures of FIGS. 2A-2C.

Referring FIGS. 2D-2E, gate contact opening 232* is formed in FET 200 after the formation of S/D contact structures 230. Gate contact opening 232* can be formed on gate metal fill layer 224 by forming a patterned masking layer 234 (e.g., a photoresist layer) on ILD layer 218C using a photolithographic process, which can be followed by etching ILD layers 218B-218C, ESL 217B, and gate capping layer 226 through patterned masking layer 234 to form the structures of FIGS. 2D-2E. Gate contact opening 232* can have similar dimensions W1 and W2 along X- and Y-axes and the sidewalls of gate contact opening 232* can have similar angles B along ZY- and ZX-planes.

The formation of gate contact opening 232* can be followed by the formation of gate contact opening 232**, as shown in FIGS. 2F-2G, using IBE system 100. Gate contact opening 232** can be formed by performing a directional etch process of IBE system 100 on the structures of FIGS. 2D-2E. The directional etch process of IBE system 100 can expand the dimensions of gate contact opening 232* in one direction along a Y-axis (as shown in FIG. 2G) without changing the dimensions of gate contact opening 232* along an X-axis (as shown in FIG. 2F). As a result, dimensions W1 and W2 of gate contact opening 232* along a Y-axis is expanded to respective dimensions W3 and W4 of gate contact opening 232**. In some embodiments, for the directional etch process, the pressure of IBE system 100 can be set in a range from about 0.15 mT to about 0.2 mT, a screen grid voltage of 1.2 KV, while the accelerate elements can be supplied by voltages as shown in Table 1.

In some embodiments, similar to gate contact structures 232, S/D contact structures 230 can also be formed with different dimensions along X- and Y-axes using IBE system 100.

FIGS. 2H-2I illustrate top views of directional etching to form merged gate contact structure 248 of parallel FETs 241A-241C of semiconductor device 250 using IBE system 100. Each of FETs 241A-241C can be similar to FET 200. Merged gate contact structure 248 (shown in FIG. 2J) can be formed by connecting gate contact structures 233A-233C of respective FETs 241A-241C. Each of gate contact structures 233A-233C can have dimension W1 along an X-axis and dimension W3 along a Y-axis, similar to gate contact structure 232.

FIG. 2H illustrates a top view of semiconductor device 250 with parallel FETs 241A-241C after the formation of gate contact openings 231A-231C, similar to gate contact opening 232*. For simplicity, S/D contact structures 242 and gate contact openings 231A-231C are shown on active layers 242 of FETs 241A-241C. FETs 241A-241C can be separated from each other by IDL layer 246. FIG. 2I illustrates a top view of semiconductor device 250 after the formation of gate contact openings 231A*-231C* using IBE system 100, similar to gate contact opening 232**. Gate contact openings 231A*-231C* can have dimensions similar to gate contact opening 232**. The formation of gate contact openings 231A*-231C* can be followed by filling the gate contact openings 231A*-231C* with conductive material to form the merged gate contact structure 248 of FIG. 2J.

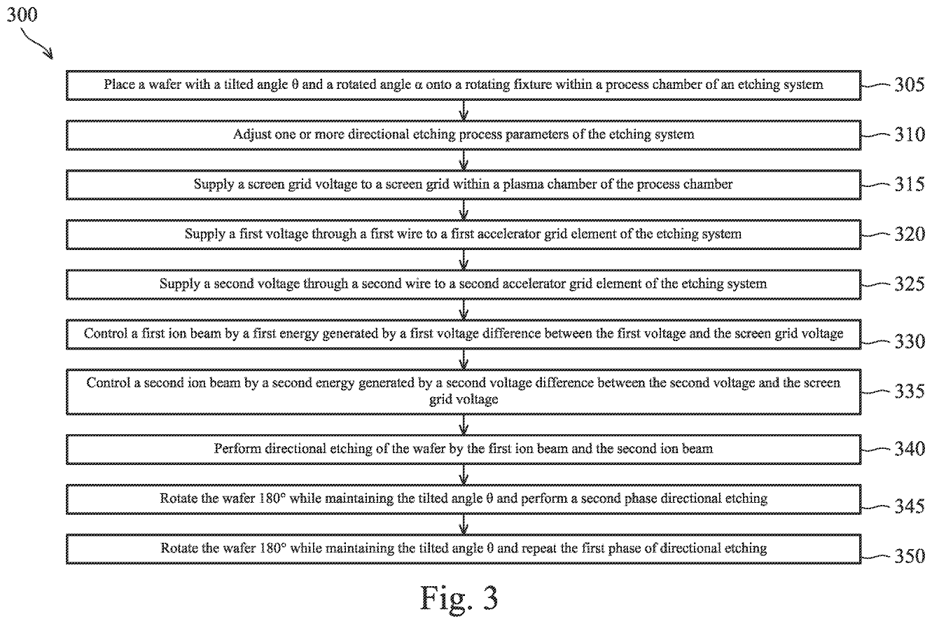

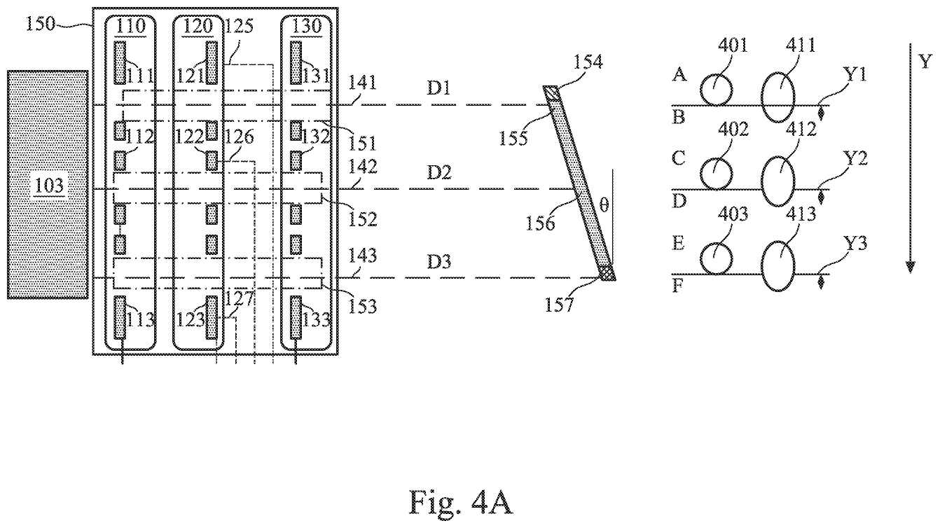

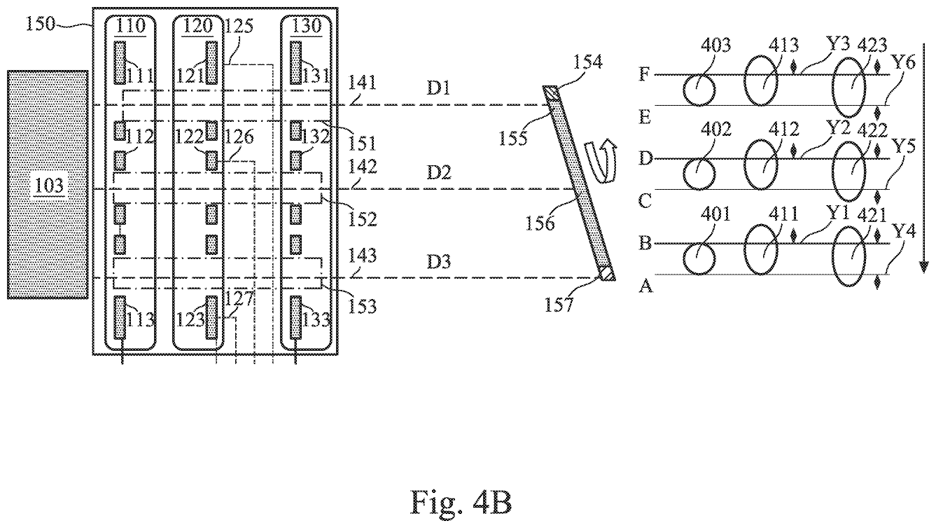

FIG. 3 is a flow chart of a method 300 for performing directional etching by an etching system, in accordance with some embodiments. This disclosure is not limited to this operational description. Rather, other operations are within the spirit and scope of the present disclosure. It is to be appreciated that additional operations can be performed. Moreover, not all operations can be needed to perform the disclosure provided herein. Further, some of the operations can be performed simultaneously, or in a different order than shown in FIG. 3. In some implementations, one or more other operations can be performed in addition to or in place of the presently described operations. For illustrative purposes, method 300 is described with reference to the embodiments of FIG. 1A-1C, or 2A-2J, or FIG. 4A-4B. However, method 300 is not limited to these embodiments.

In some embodiments, to perform directional etching, wafer 154 is placed on a rotating fixture 107 in process chamber 101, which can be a vacuum chamber. A gas is introduced through inlet 102. The pressure of process chamber 101 can be reduced in a range from about 0.15 mT to about 0.2 mT. An RF plasma generator can be turned on and a plasma is struck (ignited) within the plasma chamber 103. Ions are extracted by screen grid 110, and further accelerated by accelerator grid 120 as they move toward the wafer to form ion beams, e.g., ion beam 141, ion beam 142, ion beam 143. Ions in the ion beams hit wafer 154, sputtering materials from the surface. The process continues until pattern is etched exposing the underlying layer for wafer 154. The high level description of the process is described below in more details in various operations.

In operation 305 of FIG. 3, a wafer is placed onto a rotating fixture within a process chamber of an etching system, where the wafer has a tilted angle θ and a rotated angle of a. For example, as shown and discussed with reference to FIG. 1A, wafer 154 is placed onto rotating fixture 107 within process chamber 101 of IBE system 100, where wafer 154 has a tilted angle θ and a rotated angle of a.

In operation 310 of FIG. 3, directional etching process parameters of the etching system are adjusted. For example, as shown and discussed with reference to FIG. 1A, directional etching process parameters of IBE system 100 are adjusted to have an operation pressure between about 0.15 mT to about 0.20 mT for the process chamber, and the tilted angle θ between about 5° and 600 degrees. In addition, in some embodiments, an etching chemical can be supplied to plasma chamber 103.

In operation 315 of FIG. 3, a screen grid voltage is supplied to a screen grid to extract ions from plasma within a plasma chamber within the process chamber. For example, as shown and discussed with reference to FIG. 1B, a screen grid voltage is supplied to screen grid 110 to extract ions from plasma within plasma chamber 103 within process chamber 101.

In operation 320 of FIG. 3, a first voltage is supplied through a first wire to a first accelerator grid element of an accelerator grid of the etching system. For example, as shown and discussed with reference to FIG. 1B, a first voltage is supplied to accelerator grid element 121 of accelerator grid 120 through wire 125.

In operation 325 of FIG. 3, a second voltage is supplied through a second wire to a second accelerator grid element of an accelerator grid of the etching system. For example, as shown and discussed with reference to FIG. 1B, a second voltage is supplied to accelerator grid element 122 of accelerator grid 120 through wire 126. The second voltage is different from the first voltage.

In operation 330 of FIG. 3, a first ion beam is controlled by a first energy generated by a first voltage difference between the first voltage and the screen grid voltage, where the first ion beam has a first incidence distance from an ion source to the wafer. For example, as shown and discussed with reference to FIG. 1B, ion beam 141 is controlled by a first energy generated by a first voltage difference between the first voltage supplied to accelerator grid element 121 and the screen grid voltage supplied to screen grid 110. Ion beam 141 has a first incidence distance D1 to wafer 154.

In operation 335 of FIG. 3, a second ion beam is controlled by a second energy generated by a second voltage difference between the second voltage and the screen grid voltage, where the second ion beam has a second incidence distance from an ion source to the wafer. For example, as shown and discussed with reference to FIG. 1B, ion beam 142 is controlled by a second energy generated by a second voltage difference between the second voltage supplied to accelerator grid element 122 and the screen grid voltage supplied to screen grid 110. Ion beam 142 has a second incidence distance D2 to wafer 154, where D2 is different from D1.

In operation 340 of FIG. 3, during a first phase of directional etching, directional etching is performed on the wafer by the first ion beam and the second ion beam. For example, as shown and discussed with reference to FIG. 1B, during a first phase of directional etching, directional etching is performed on wafer 154 by multiple ion beams through the multiple holes including ion beam 141 and ion beam 142.

In operation 345 of FIG. 3, the wafer is rotated 180° to have a rotated angle of 180°+α degree while maintaining the tilted angle θ, and a second phase directional etching is performed on the wafer by the multiple ion beams. For example, as shown and discussed with reference to FIG. 1A, wafer 154 is rotated 180° to have a rotated angle of 180°+α degree while maintaining the tilted angle θ. Moreover, a second phase directional etching is performed on wafer 154 by the multiple ion beams, e.g., ion beam 141, ion beam 142, and ion beam 143.

In operation 350 of FIG. 3, the wafer is rotated 180° to have the rotated angle of α degree while maintaining the tilted angle θ, and the first phase of directional etching on the wafer is repeated. For example, as shown and discussed with reference to FIG. 1B, wafer 154 is rotated 180° to have the rotated angle of α degree while maintaining the tilted angle θ, and the first phase of directional etching on wafer 154 is repeated.

FIGS. 4A-4B illustrate further details of directional etching performed on features of a semiconductor device using an IBE system, in accordance with some embodiments. A RF plasma generator can be turned on and a plasma is struck (ignited) within the plasma chamber 103. FIG. 4A shows more details for operation 340 of FIG. 3, while FIG. 4B shows more details for operation 345 of FIG. 3.

Ions are extracted by screen grid 110, and further accelerated by accelerator grid 120 as they move toward the wafer to form ion beams, e.g., ion beam 141, ion beam 142, ion beam 143. Ion beam 141 moves through hole 151, ion beam 142 moves through hole 152, and ion beam 143 moves through hole 153. Ions in the ion beams hit wafer 154, sputtering materials from the surface. Ion beam 141 having the incidence distance D1 reaches the surface of wafer 154 at incidence point 155. Similarly, ion beam 142 having the incidence distance D2 reaches incidence point 156, and ion beam 143 having the incidence distance D3 reaches incidence point 157. Wafer 154 can have a feature 401 at incidence point 155, have a feature 402 at incidence point 156, and have a feature 403 at incidence point 157.

As shown in FIG. 4A, during the first phase of the directional etching performed during operation 340 of FIG. 3, the features are extended in one direction. In detail, feature 401 is extended along a Y-axis beyond the line Y1 to become feature 411, feature 402 is extended along the Y-axis beyond the line Y2 to become feature 412, and feature 403 is extended along the Y-axis beyond the line Y3 to become feature 413. Accelerator grid element 123 is supplied by the third voltage to generate an electric field of the highest energy for ion beam 143 with the longest incidence distance D3, accelerator grid element 122 is supplied by the second voltage to generate an electric field of the second highest energy for ion beam 142 with the second longest incidence distance D2, and accelerator grid element 121 is supplied by the first voltage to generate an electric field of the lowest energy for ion beam 141 with the shortest incidence distance D1. Therefore, feature 401 at incidence point 155, feature 402 at incidence point 156, and feature 403 at incidence point 157, all have a same etching rate. As shown in FIG. 4A, feature 411 compared to feature 401, feature 412 compared to feature 402, and feature 413 compared to feature 403, all have substantially equal etching results.

As shown in FIG. 4B, before the second phase of the directional etching, wafer 154 is rotated 180 degree first. Afterwards, directional etching is performed on wafer 154 again in the second phase during operation 345 of FIG. 3. Features 413, 412, and 411 are extended in one direction. In detail, feature 411 is extended along the Y-axis beyond the line Y4 to become feature 421, feature 412 is extended along the Y-axis beyond the line Y5 to become feature 422, and feature 413 is extended along the Y-axis beyond the line Y6 to become feature 423. Feature 421 compared to feature 411, feature 422 compared to feature 412, and feature 423 compared to feature 413, all have substantially equal etching results.

The present disclosure provides example three-grid system (e.g., three-grid system 150) in an IBE system (e.g., IBE system 100) for directional etching to prevent and/or mitigate the asymmetry etching behavior of a current IBE system. An IBE system with the example three-grid system can generate improved or close to uniformly distributed etching across different locations of a surface of a tilted wafer within the process chamber of the IBE system. The three-grid system includes a screen grid, an accelerator grid, and a decelerator grid to control the ion beams to strike the wafer. Instead of having a same accelerator voltage supplied to different accelerator grid elements, some embodiments have different voltages supplied to different accelerator grid elements. As a result, an accelerator grid element controlling an ion beam having a longer incidence distance can be supplied by a voltage to create an electric field with larger energy to transport the ions in the ion beam. Accordingly, the multiple accelerate grid voltages for multiple accelerate grid elements are able to balance all locations in the rotated tilted wafer with equal directional etching amounts. As a result, embodiments herein reduce IBE asymmetry etching behavior.

In some embodiments, a method for directional etching by an IBE system includes placing a wafer onto a rotating fixture within a process chamber of the IBE system, where the wafer has a tilted angle θ and a rotated angle of α. The method further includes setting up one or more directional etching process parameters of the IBE system. In addition, the method includes assigning a screen grid voltage to supply a screen grid included in a three-grid system to extract ions from plasma within a plasma chamber within the process chamber. The three-grid system includes the screen grid, an accelerator grid, and a decelerator grid with multiple holes including a first hole and a second hole through the screen grid, the accelerator grid, and the decelerator grid. Moreover, the method includes assigning a first voltage to supply a first accelerator grid element of the accelerator grid through a first wire, and assigning a second voltage different from the first voltage to supply a second accelerator grid element of the accelerator grid through a second wire. The first accelerator grid element controls a first ion beam through the first hole, while the second accelerator grid element controls a second ion beam through the second hole. The first ion beam has a first incidence distance to the wafer, and the second ion beam has a second incidence distance to the wafer different from the first incidence distance. In addition, the method includes performing directional etching of the wafer by multiple ion beams through the multiple holes including the first ion beam and the second ion beam.

In some embodiments, an IBE system includes a process chamber. The process chamber includes a plasma chamber configured to provide plasma. In addition, the process chamber includes a screen grid having multiple screen grid elements in contact with the plasma chamber, and an accelerator grid having multiple accelerator grid elements including a first accelerator grid element and a second accelerator grid element. The screen grid is supplied by a screen grid voltage to extract ions from the plasma within the plasma chamber. A first wire is coupled to the first accelerator grid element and configured to supply a first voltage to the first accelerator grid element. A second wire is coupled to the second accelerator grid element and configured to supply a second voltage to the second accelerator grid element, wherein the second voltage is different from the first voltage. Multiple holes including a first hole and a second hole through the screen grid and the accelerator grid are configured to provide multiple ion beams. The process chamber further includes a rotating fixture configured to hold a wafer having a tilted angle. A first ion beam through the first hole controlled by the first accelerator grid element has a first incidence distance to the wafer, and a second ion beam through the second hole controlled by the second accelerator grid element has a second incidence distance to the wafer. The second incidence distance is different from the first incidence distance. The first ion beam and the second ion beam perform directional etching on the wafer.

In some embodiments, a method for directional etching by an IBE system includes assigning a screen grid voltage to supply a screen grid included in a three-grid system to extract ions from plasma within a plasma chamber within a process chamber of the IBE system. The three-grid system includes the screen grid, an accelerator grid, and a decelerator grid with multiple holes including a first hole and a second hole through the screen grid, the accelerator grid, and the decelerator grid. Moreover, the method includes assigning a first voltage to supply a first accelerator grid element of the accelerator grid through a first wire, and assigning a second voltage different from the first voltage to supply a second accelerator grid element of the accelerator grid through a second wire. The first accelerator grid element controls a first ion beam through the first hole, while the second accelerator grid element controls a second ion beam through the second hole. The first ion beam has a first incidence distance to the wafer, and the second ion beam has a second incidence distance to the wafer different from the first incidence distance. In addition, the method includes performing a first phase of directional etching of the wafer by multiple ion beams through the multiple holes including the first ion beam and the second ion beam. Afterwards, the method includes rotating the wafer 180° to have a rotated angle of 180°+α degree while maintaining the tilted angle θ, and further performing a second phase directional etching of the wafer by the multiple ion beams.

The foregoing disclosure outlines features of several embodiments so that those skilled in the art can better understand the aspects of the present disclosure. Those skilled in the art should appreciate that they can readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they can make various changes, substitutions, and alterations herein without departing from the spirit and scope of the present disclosure.

1. An ion beam etching (IBE) system, comprising:
a plasma chamber configured to provide plasma;
a screen grid in contact with the plasma chamber, wherein the screen grid is configured to receive a screen grid voltage to extract ions from the plasma within the plasma chamber;
an accelerator grid comprising a first accelerator grid element and a second accelerator grid element, wherein the accelerator grid is disposed adjacent to and separated from the screen grid;
a decelerator grid disposed adjacent to and separated from the accelerator grid;
a first wire coupled to the first accelerator grid element, wherein the first wire is configured to supply a first voltage to the first accelerator grid element to control a first ion beam through a first hole that extends through the screen grid, the accelerator grid, and the decelerator grid;
a second wire coupled to the second accelerator grid element, wherein the second wire is configured to supply a second voltage to the second accelerator grid element to control a second ion beam through a second hole that extends through the screen grid, the accelerator grid, and the decelerator grid, wherein the second voltage is different from the first voltage; and
a rotating fixture configured to hold a wafer with a tilted angle, wherein the first ion beam has a first incidence distance from an ion source to the wafer, the second ion beam has a second incidence distance from the ion source to the wafer, and the second incidence distance is different from the first incidence distance.

2. The IBE system of claim 1, wherein the first ion beam is controlled by a first energy generated by a first voltage difference between the first voltage and the screen grid voltage,
wherein the second ion beam is controlled by a second energy generated by a second voltage difference between the second voltage and the screen grid voltage, and
wherein the first energy is smaller than the second energy, and the first incidence distance for the first ion beam is shorter than the second incidence distance for the second ion beam.

3. The IBE system of claim 1, wherein the screen grid voltage is a positive voltage with respect to a ground voltage, and
wherein the first voltage and the second voltage are negative voltages with respect to the ground voltage.

4. The IBE system of claim 1, wherein the screen grid voltage is about 1200 volt, the first voltage is about −200 volt, and the second voltage is about −240 volt.

5. The IBE system of claim 1, wherein the rotating fixture is configured to rotate the wafer.

6. The IBE system of claim 1, wherein the accelerator grid comprises a third accelerator grid element, and wherein the IBE system further comprises:
a third wire coupled to the third accelerator grid element, wherein the third wire is configured to supply a third voltage to the third accelerator grid element to control a third ion beam through a third hole, wherein the third ion beam has a third incidence distance from the ion source to the wafer, wherein the third voltage is different from the second voltage and the first voltage, and wherein the third incidence distance is different from the second incidence distance and the first incidence distance.

7. The IBE system of claim 1, further comprising:
a first zone comprising the first hole and a first group of one or more additional holes controlled by a first group of one or more accelerator grid elements coupled to the first wire to supply the first voltage to the first group of one or more accelerator grid elements; and
a second zone comprising the second hole and a second group of one or more additional holes controlled by a second group of one or more accelerator grid elements coupled to the second wire to supply the second voltage to the second group of one or more accelerator grid elements, wherein the second zone is separated from the first zone by an insulator.

8. The IBE system of claim 1, further comprising:
a control unit configured to control the first wire to supply the first voltage to the first accelerator grid element, and control the second wire to supply the second voltage to the second accelerator grid element.

9. The IBE system of claim 1, further comprising:
a mechanical shutter disposed between the plasma chamber and the rotating fixture, wherein the screen grid, the accelerator grid, and the decelerator grid are disposed between the plasma chamber and the mechanical shutter.

10. The IBE system of claim 1, further comprising:
a plasma bridge neutralizer configured to provide electrons to neutralize the first ion beam and the second ion beam.

11. The IBE system of claim 1, further comprising:
a secondary ions mass spectrometer configured to collect secondary ions ejected from the wafer.

12. An ion beam etching (IBE) system, comprising:
a plasma chamber configured to provide plasma;
a screen grid in contact with the plasma chamber, wherein the screen grid is configured to receive a screen grid voltage to extract ions from the plasma within the plasma chamber;
an accelerator grid comprising a plurality of accelerator grid elements comprising a first accelerator grid element and a second accelerator grid element, wherein the accelerator grid is disposed adjacent to and separated from the screen grid;
a first zone comprising a first group of one or more holes extending through the screen grid and the accelerator grid and controlled by a first group of one or more accelerator grid elements supplied by a first voltage, wherein the first zone comprises a first hole, and the first accelerator grid element is configured to control a first ion beam through the first hole; and
a second zone comprising a second group of one or more holes extending through the screen grid and the accelerator grid and controlled by a second group of one or more accelerator grid elements supplied by a second voltage, wherein the second zone is separated from the first zone by an insulator, wherein the second voltage is different from the first voltage, wherein the second zone comprises a second hole, and the second accelerator grid element is configured to control a second ion beam through the second hole; and
a rotating fixture configured to hold a wafer with a tilted angle, wherein the first ion beam has a first incidence distance from an ion source to the wafer, the second ion beam has a second incidence distance from the ion source to the wafer, and the second incidence distance is different from the first incidence distance.

13. The IBE system of claim 12, further comprising:
a first wire coupled to the first group of one or more accelerator grid elements to supply the first voltage to the first group of one or more accelerator grid elements; and
a second wire coupled to the second group of one or more accelerator grid elements to supply the second voltage to the second group of one or more accelerator grid elements.

14. The IBE system of claim 12, wherein the first ion beam is controlled by a first energy generated by a first voltage difference between the first voltage and the screen grid voltage, the second ion beam is controlled by a second energy generated by a second voltage difference between the second voltage and the screen grid voltage, and wherein the first energy is smaller than the second energy, and the first incidence distance for the first ion beam is shorter than the second incidence distance for the second ion beam.

15. The IBE system of claim 12, wherein the screen grid voltage is a positive voltage with respect to a ground voltage, and
wherein the first voltage and the second voltage are negative voltages with respect to the ground voltage.

16-20. (canceled)

21. An apparatus, comprising:
a screen grid configured to extract ions from a plasma chamber and to be positively biased relative to a ground voltage;
an accelerator grid adjacent to the screen grid and configured to accelerate the ions, wherein the accelerator grid comprises:
a first accelerator grid element negatively biased relative to the ground voltage by a first voltage; and
a second accelerator grid element negatively biased relative to the ground voltage by a second voltage different from the first voltage; and
a decelerator grid adjacent to the accelerator grid and configured to be biased at the ground voltage.

22. The apparatus of claim 21, wherein the first and second voltages are between about −100 V and about −400 V.

23. The apparatus of claim 21, further comprising first and second holes through the screen grid, the accelerator grid, and the decelerator grid, wherein:
a first ion beam through the first hole is configured to be controlled by a first energy generated by the first voltage; and
a second ion beam through the second hole is configured to be controlled by a second energy generated by the first voltage, wherein the second energy is different from the first energy.

24. The apparatus of claim 23, wherein:
the first hole comprises:
a first aperture on the screen grid and having a first diameter; and
a second aperture on the accelerator grid and having a second diameter smaller than the first diameter; and
the second hole comprises:
a third aperture on the screen grid and having the first diameter; and
a fourth aperture on the accelerator grid and having the second diameter.

25. The apparatus of claim 21, wherein the accelerator grid further comprises a third accelerator grid element separated from the first and second accelerator grid elements, wherein the third accelerator grid element is negatively biased relative to the ground voltage by a third voltage different from the first and second voltages.
